(19) United States
(12) Patent Application Publication
(10) Pub. No.: US 2024/0059554 A1
(43) Pub. Date: Feb. 22, 2024

(54) MEMS MODULE

(71) Applicant: ROHM CO., LTD., Kyoto (JP)

(72) Inventors: Toru HIGUCHI, Kyoto (JP); Kosuke YAMASHIRO, Kyoto (JP)

(73) Assignee: ROHM CO., LTD., Kyoto (JP)

(21) Appl. No.: 18/365,554

(22) Filed: Aug. 4, 2023

(30) Foreign Application Priority Data
Aug. 19, 2022 (JP) 2022-131049

(51) Int. Cl. B81B 3/00; B81B 7/00; G01L 9/00

(52) U.S. Cl. CPC B81B 3/0086; B81B 7/007; B81B 7/0048; G01L 9/0051

(57) ABSTRACT

A MEMS module includes a MEMS element provided with a substrate in which a hollow portion is formed, the MEMS element including a movable portion of the substrate which covers the hollow portion and has a thickness that allows a shape of the movable portion to be deformable, a first gauge resistor arranged on the substrate such that at least a portion of the first gauge resistor overlaps with the hollow portion, and a second gauge resistor arranged on the substrate in a region surrounding the first gauge resistor without overlapping with the hollow portion, and an electronic component configured to correct detection information of the MEMS element by using a first electrical signal detected by the first gauge resistor and a second electrical signal detected by the second gauge resistor and calculate an amount of change in air pressure.

### CROSS-REFERENCE TO RELATED APPLICATION

This application is based upon and claims the benefit of priority from Japanese Patent Application No. 2022-131049, filed on Aug. 19, 2022, the entire contents of which are incorporated herein by reference.

### TECHNICAL FIELD

The present disclosure relates to a MEMS module.

### BACKGROUND

There is known a MEMS (Micro Electro-Mechanical System) element, which is a device in which mechanical elements and electronic circuits are integrated by using a microfabrication technique used when manufacturing a semiconductor integrated circuit.

The MEMS element has, for example, a hollow portion and a movable portion which closes the hollow portion. In a configuration of the related art, the hollow portion is formed by bonding a glass substrate to a back side of a Si substrate having a recess portion. This bonding is required such that a minute gap is not generated when the hollow portion is sealed.

Further, the MEMS element may be used by being incorporated into a pressure sensor. A change in air pressure changes a stress generated at the end of the movable portion of the MEMS element, and a gauge resistance is changed according to the deformation of the movable portion. The pressure sensor outputs a change in its gauge resistance as a change in output voltage.

### BRIEF DESCRIPTION OF DRAWINGS

The accompanying drawings, which are incorporated in and constitute a part of the specification, illustrate embodiments of the present disclosure.

FIG. 1 is a perspective view showing a MEMS module according to the present embodiment.

FIG. 2 is a perspective view of a main part showing a MEMS module according to the present embodiment.

FIG. 3 is a cross-sectional view taken along line III-III in FIG. 1.

FIG. 4 is a cross-sectional view showing an example of a MEMS element according to the present embodiment.

FIG. 5 is a cross-sectional view (first cross-sectional view) showing a method of manufacturing an example of a MEMS element according to the present embodiment.

FIG. 6 is a cross-sectional view (second cross-sectional view) showing a method of manufacturing an example of a MEMS element according to the present embodiment.

FIG. 7 is a cross-sectional view (third cross-sectional view) showing a method of manufacturing an example of a MEMS element according to the present embodiment.

FIG. 8 is a cross-sectional view (fourth cross-sectional view) showing a method of manufacturing an example of a MEMS element according to the present embodiment.

FIG. 9 is a cross-sectional view (fifth cross-sectional view) showing a method of manufacturing an example of a MEMS element according to the present embodiment.

FIG. 10 is a cross-sectional view (sixth cross-sectional view) showing a method of manufacturing an example of a MEMS element according to the present embodiment.

FIG. 11 is a layout diagram showing a MEMS module according to the present embodiment.

FIG. 12 is a schematic top view showing a MEMS module according to the present embodiment.

FIG. 13 is an equivalent circuit diagram showing a MEMS module according to the present embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Next, the present embodiment will be described with reference to the drawings. In the description of the drawings described below, the same or similar parts are denoted by the same or similar reference numerals. However, it should be noted that the drawings are schematic, and the relationship between the thickness and plan-view dimensions of each component, etc., differs from the actual one. Therefore, specific thicknesses and dimensions should be determined with reference to the following description. In addition, it goes without saying that there are portions with different dimensional relationships and ratios between the drawings.

Further, the embodiment described below is an example of an apparatus and a method for embodying technical ideas, and is not intended to specify the material, shape, structure, arrangement, etc. of each component. Various modifications can be made to the present embodiment within the scope defined by the claims.

One specific aspect of the present embodiment is as follows.

<1> A MEMS module, comprising: a MEMS element provided with a substrate in which a hollow portion is formed, the MEMS element including a movable portion of the substrate which covers the hollow portion and has a thickness that allows a shape of the movable portion to be deformable by an air pressure difference between an air pressure inside the hollow portion and an air pressure outside the substrate, a first gauge resistor arranged on the substrate such that at least a portion of the first gauge resistor overlaps with the hollow portion when viewed in a thickness direction of the movable portion, and a second gauge resistor arranged on the substrate in a region surrounding the first gauge resistor without overlapping with the hollow portion when viewed in the thickness direction of the movable portion; and an electronic component configured to correct detection information of the MEMS element by using a first electrical signal detected by the first gauge resistor and a second electrical signal detected by the second gauge resistor and calculate an amount of change in air pressure.

<2> The MEMS module of <1>, wherein the correction of the detection information is performed by subtracting a voltage difference generated by a change in resistance value of the second gauge resistor with respect to a voltage detected in a circuit including the second gauge resistor from a voltage difference generated by a change in resistance value of the first gauge resistor with respect to a voltage detected in a circuit including the first gauge resistor.

<3> The MEMS module of <1> or <2>, further comprising: a wiring having a region located on an outer edge side of the substrate when viewed in a direction perpendicular to the thickness direction of the movable portion, wherein the first electrical signal and the second electrical signal are transmitted from the MEMS element to the electronic component via the wiring.

According to <1> to <3>, the electronic component corrects the detection information of the MEMS element by using the first electrical signal detected by the first gauge resistor and the second electrical signal detected by the second gauge resistor. Specifically, the electronic component corrects the detection information of the MEMS element by subtracting the voltage difference generated by the change in resistance value of the second gauge resistor from the voltage difference generated by the change in resistance value of the first gauge resistor. Therefore, it is possible to provide a MEMS module capable of accurately deriving a change in outside air pressure.

<4> The MEMS module of any one of <1> to <3>, wherein the electronic component is mounted on the substrate, and wherein the MEMS element and the electronic component are spaced apart from each other.

According to <4>, it is possible to suppress the influence of stress or the like applied to the electronic component from directly affecting the MEMS element, and it is possible to derive the change in outside air pressure more accurately.

<5> The MEMS module of any one of <1> to <4>, further comprising: a stress relaxation material arranged between the MEMS element and the electronic component.

According to <5>, the influence of an external stress applied to the electronic component can be reduced by the stress relaxation material, and the influence of the external stress applied to the electronic component on the MEMS element can be suppressed. This makes it possible to derive the change in outside air pressure more accurately.

<6> The MEMS module of any one of <1> to <5>, wherein the first gauge resistor and the second gauge resistor have a structure identical to each other.

According to <6>, there is no need to correct the difference in an electrical signal due to the difference in the structure of the two gauge resistors (the first gauge resistor and the second gauge resistor) themselves, and the change in external air pressure can be derived more accurately.

<7> The MEMS module of any one of <1> to <6>, wherein the first gauge resistor and the second gauge resistor are spaced apart from each other when viewed in a direction perpendicular to the thickness direction of the movable portion.

According to <7>, since the first gauge resistor is spaced apart from the second gauge resistor, it is possible to suppress the influence of the gauge resistors on each other, and it is possible to derive the change in external air pressure more accurately.

<8> The MEMS module of any one of <1> to <7>, wherein the substrate is made of silicon.

According to <8>, the MEMS element can be easily formed by using silicon, which is easy to process, as the substrate.

A MEMS module A1 according to the present embodiment will be described.

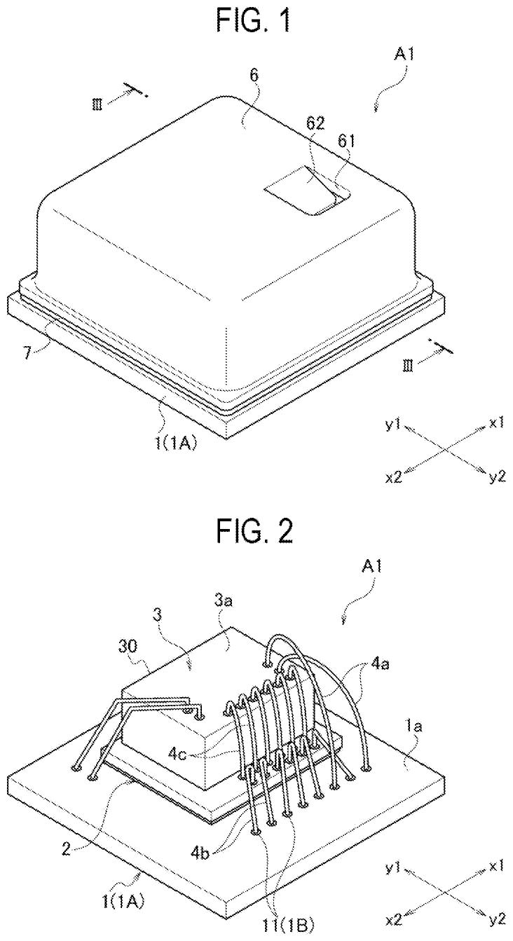

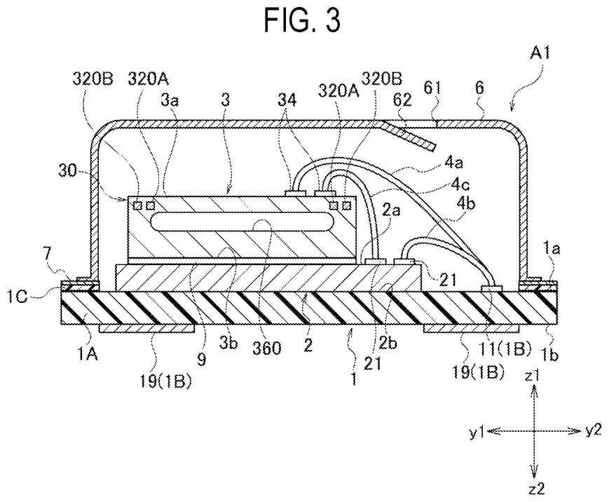

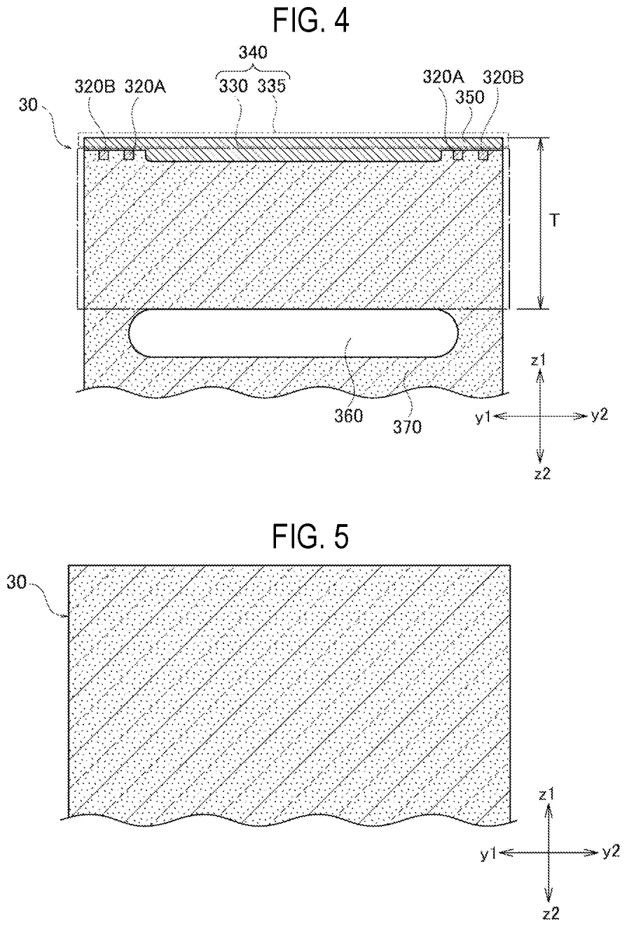

FIG. 1 is a perspective view showing the MEMS module A1. FIG. 2 is a perspective view of a main part in which the illustration of some configurations of the MEMS module A1 (a cover 6, a joining material 7, etc., which will be described later) shown in FIG. 1 is omitted. FIG. 3 is a cross-sectional view taken along line III-III in FIG. 1. FIG. 4 is a cross-sectional view showing an example of the MEMS element 3 and its periphery in the MEMS module A1. The MEMS module A1 includes a substrate 1, an electronic component 2, a MEMS element 3 including a first gauge resistor 320A and a second gauge resistor 320B, a plurality of wirings 4a to 4c, a cover 6, and a joining material 7. The MEMS module A1 of the present embodiment is configured to detect an air pressure, and is surface-mounted on a circuit board of various electronic devices such as, for example, a mobile terminal and the like. For example, in a mobile terminal, the MEMS module A1 detects an atmospheric pressure. The detected atmospheric pressure is used as information for calculating, for example, an altitude.

In the present embodiment, the thickness direction (plan-view direction) of the MEMS module A1 is defined as a z direction (z1-z2 direction), the direction along one side of the MEMS module A1, which is perpendicular to the z direction, is defined as an x direction (x1-x2 direction), and the direction, which is perpendicular to the z direction and the x direction, is defined as a y direction (y1-y2 direction). In the present embodiment, the MEMS module A1 has, for example, an x-direction dimension of about 2 mm, a y-direction dimension of about 2 mm, and a z-direction dimension of about 0.8 mm to 1 mm.

As shown in FIG. 2, the substrate 1 is a member on which an electronic component 2 is loaded and which is configured to mount the MEMS module A1 on a circuit board of various electronic devices. As shown in FIG. 3, the substrate 1 includes a base material 1A, wiring portions 1B, and an insulating layer 1C. The specific configuration of the substrate 1 is not particularly limited as long as it can appropriately support the electronic component 2 and the like, and may include, for example a printed circuit board.

The base material 1A is made of an insulator and is a main constituent member of the substrate 1. As the base material 1A, there are, for example, a glass epoxy resin, a polyimide resin, a phenol resin, and ceramics. The base material 1A has, for example, a rectangular plate shape in a plan view, and has a holding surface 1a and a mounting surface 1b. The holding surface 1a and the mounting surface 1b face opposite sides in the thickness direction (z direction) of the substrate 1. The holding surface 1a is a surface facing the z1 direction, and is a surface on which the electronic component 2 is held. The mounting surface 1b is a surface facing the z2 direction, and is a surface used when mounting the MEMS module A1 on circuit boards of various electronic devices. In the present embodiment, the z-direction dimension of the substrate 1 is about 100 to 200 μm, the x-direction dimension thereof is about 2 mm, and the y-direction dimension thereof is about 2 mm.

The wiring portions 1B form conductive paths for electrically connecting the electronic component 2 and the MEMS element 3 to a circuit or the like outside the MEMS module A1. The wiring portions 1B are made of one type or plural types of metal such as, for example, Cu, Ni, Ti, Au, and the like, and are formed by plating, for example. In the present embodiment, the wiring portions 1B have a plurality of electrode pads 11 and back surface pads 19. However, these are examples of specific configurations of the wiring portions 1B, and the configuration thereof is not particularly limited.

The electrode pads 11 are formed on the holding surface 1a of the base material 1A and are a plurality of independent regions spaced apart from one another. An end portion of a wiring 4a and an end portion of a wiring 4b are bonded to the electrode pads 11.

The back surface pads 19 are provided on the mounting surface 1b, and are electrically connected to the electrode pads 11 via internal wirings (not shown) formed inside the base material 1A. The back surface pads 19 are used as electrodes for electrically connecting the circuit pattern of the circuit board with the electrode pads 11 when mounting the MEMS module A1 on the circuit board or the like.

The insulating layer 1C covers appropriate regions of the wiring portions 1B to insulate and protect the regions. The insulating layer 1C is made of an insulating material, and is formed of, for example, a resist resin. The insulating layer 1C may be formed, for example, in a rectangular annular shape in a plan view.

The electronic component 2 is configured to process electrical signals detected by a sensor, and is configured as a so-called ASIC (Application Specific Integrated Circuit) element. The electronic component 2 may include, for example, a temperature sensor. As will be described later in detail, the electronic component 2 may process the electrical signal detected by the temperature sensor, the electrical signal detected by the first gauge resistor 320A, and the electrical signal detected by the second gauge resistor 320B.

The electronic component 2 is a package in which various elements such as the MEMS element 3 and the like are mounted on a substrate. As shown in FIG. 3, the electronic component 2 has a rectangular plate shape in a plan view, and includes a substrate having a main surface 2a and a mounting surface 2b. The main surface 2a and the mounting surface 2b face opposite sides in the thickness direction (z direction) of the electronic component 2. In the present embodiment, the main surface 2a is a holding surface on which the MEMS element 3 is held, and the mounting surface 2b is used when mounting the electronic component 2 on the substrate 1. The z-direction dimension of the electronic component 2 is, for example, about 100 to 300 μm, the x-direction dimension thereof is, for example, about 1 to 1.2 mm, and the y-direction dimension thereof is, for example, about 1 to 4.2 mm.

The electronic component 2 is held on the holding surface 1a of the substrate 1 at a portion shifted toward the x1 direction. A plurality of electrode pads 21 are provided on the main surface 2a of the electronic component 2. The electrode pads 21 are conductively joined to the electrode pads 11 of the substrate 1. The electrode pad 21 is joined to a second end of the wiring 4b having a first end joined to the electrode pad 11. Further, the electrode pad 21 is conductively joined to the electrode pad 34 of the MEMS element 3. The electrode pad 21 is joined to a second end of the wiring 4c having a first end joined to the electrode pad 34. The electrode pad 21 is made of a metal such as Al or an aluminum alloy, and is formed by sputtering or plating, for example. In the present embodiment, an Al layer formed by sputtering is used as the electrode pad 21. The electrode pad 21 is connected to a wiring pattern on the main surface 2a. Alternatively, the electrodes of the electronic component 2 and the electrodes of the substrate 1 may be electrically connected to each other by bumps instead of the wirings 4b. In this specification and the like, “electrically connected” includes a case of being connected via “something that has an electrical action.” Here, “something that has an electrical action” is not particularly limited as long as it enables transmission and reception of electrical signals between connection objects. For example, “something that has an electrical action” includes electrodes, wirings, switching elements, resistive elements, inductors, capacitive elements, and other elements having various functions. The method of joining the electronic component 2 and the substrate 1 is not particularly limited. For example, the electronic component 2 may be conductively joined to the substrate 1 via a stress relaxation material such as a silicon resin or a die attachment film.

The MEMS element 3 is configured as an air pressure sensor for detecting a pressure. The MEMS element 3 detects an air pressure and outputs the detected information to the electronic component 2 as an electrical signal. Specifically, the first electrical signal detected by the first gauge resistor 320A and the second electrical signal detected by the second gauge resistor 320B are transmitted from the MEMS element 3 to the electronic component 2 via the wiring 4c. As shown in FIG. 3, the MEMS element 3 includes a substrate 30 having a main surface 3a and a mounting surface 3b. The main surface 3a and the mounting surface 3b face opposite sides in the thickness direction (z direction) of the substrate 30. The main surface 3a is a surface facing the z1 direction. The mounting surface 3b is a surface facing the z2 direction, and is a surface used when mounting the MEMS element 3 on the electronic component 2. In the present embodiment, the z-direction dimension of the MEMS element 3 is, for example, about 200 to 300 μm, the x-direction dimension thereof is, for example, about 1 to 1.2 mm, and the y-direction dimension thereof is, for example, about 1 mm to 1.2 mm.

The MEMS element 3 is held on the main surface 2a side of the electronic component 2. The MEMS element 3 and the electronic component 2 are joined to each other by a stress relaxation material 9 such as a silicon resin or a die attachment film. However, the present disclosure is not limited thereto. The electronic component 2 and the MEMS element 3 are spaced apart from each other in the z direction. Since the MEMS element 3 is spaced apart from the electronic component 2, it is possible to suppress the influence of stress or the like applied to the electronic component 2 from directly affecting the MEMS element 3, and it is possible to derive the change in outside air pressure with high precision.

The substrate 30 includes a semiconductor layer. As the semiconductor layer, there is, for example, a silicon layer. The substrate 30 may be made of, for example, only silicon, or may be made of a stacked film of an oxide layer such as a silicon oxide layer or the like and a silicon layer. From the viewpoint of ease of processing, it is desirable that the substrate 30 is made of silicon.

As shown in FIG. 4, a hollow portion 360 of the MEMS element 3 is provided inside the substrate 30. A region around the hollow portion 360 and a portion of the substrate 30 constitute a movable portion 340 of the MEMS element 3. Furthermore, the substrate 30 is provided with a fixed portion 370 for the MEMS element 3.

The movable portion 340 overlaps with the hollow portion 360 in the z direction and is movable in the z direction to detect an air pressure. In the present embodiment, the movable portion 340 has a rectangular shape when viewed in the z direction. The film thickness T of the movable portion 340 may be any thickness that allows the shape to be deformable by the pressure difference between the air pressure inside the hollow portion 360 and the air pressure outside the substrate 30 sandwiching the movable portion 340, and is, for example, 5 to 15 μm.

The hollow portion 360 is a cavity provided within the substrate 30 and is sealed in the present embodiment. The hollow portion 360 may be a vacuum. Further, in the present embodiment, the hollow portion 360 has a rectangular shape when viewed in the z direction. However, the present disclosure is not limited thereto. The depth (z-direction dimension) of the hollow portion 360 is, for example, 5 to 15 μm.

The fixed portion 370 is a portion that supports the movable portion 340, and is a portion which is fixed to the substrate 1 when the movable portion 340 operates. In the present embodiment, the portion of the substrate 30 other than the movable portion 340 and the hollow portion 360 is used as the fixed portion 370.

In the present embodiment, the movable portion 340 and the fixed portion 370 are made of one and the same semiconductor, such as silicon, which does not have a joint at the boundary between the movable portion 340 and the fixed portion 370. The movable portion 340 has a recess portion in the region 330. The recess portion is located in a region of the movable portion 340 which overlaps with the hollow portion 360 when viewed in the z direction, and is gently recessed in the z direction.

The recess portion is formed by covering a groove portion with a portion of the substrate melted by a heat treatment, as will be described later in a manufacturing method. Since the film thickness T of the movable portion 340, which merely closes the groove portion, is thin, an interlayer film 350 may be provided on the substrate 30 in order to increase the film thickness T. In the present embodiment, when the interlayer film 350 is provided, the interlayer film 350 has a region 335 functioning as a portion of the movable portion 340. Therefore, the movable portion 340 has a region 330 of the substrate 30 and a region 335 of the interlayer film 350. The main surface 3a of the MEMS element 3 is the surface of the interlayer film 350 in the z1 direction. The interlayer film 350 may be formed by using, for example, the same material as the substrate 30, and may be made of silicon. When the interlayer film 350 is provided, the surface on which a protective film (not shown) or the like provided over the interlayer film 350 is formed is a flat surface, which is desirable so as to improve coatability of the protective film. In this specification and the like, the term “flat surface” includes a surface having an average surface roughness of 0.5 μm or less. The average surface roughness can be obtained in accordance with, for example, JISB0601:2013 or ISO25178.

The MEMS element 3 generates an electrical signal corresponding to the shape (degree of distortion) of the movable portion 340 deformed due to the difference between the air pressure inside the hollow portion 360 and the air pressure outside the substrate 30 sandwiching the movable portion 340, and outputs the electrical signal to the electronic component 2. As shown in FIG. 3, the MEMS element 3 is provided with a first gauge resistor 320A whose resistance value is changed according to deformation of the movable portion 340.

A plurality of electrode pads 34 are provided on the main surface 3a of the MEMS element 3. The electrode pads 34 are conductively joined (electrically connected) to the electrode pads 11 of the substrate 1 via the wirings 4a. The electrode pad 34 is joined to a second end of the wiring 4a having a first end connected to the electrode pad 11. Electric power is supplied from the substrate 1 to the MEMS element 3 through the wiring 4a. The electrode pad 34 is made of a metal such as Al or an aluminum alloy, and is formed by sputtering or plating, for example. The electrode pad 34 may be made of the same material as or a different material from the electrode pad 21. In the present embodiment, an Al layer formed by sputtering is used as the electrode pad 34.

The stress relaxation material 9 has an action of suppressing the influence of external stress, etc. applied to the electronic component 2 on the movable portion 340. For example, if the thickness (dimension in the z direction) of the stress relaxation member 9 is 35 μm or more, it is possible to suppress the influence of external stress on the movable portion 340. Moreover, the stress from the outside decreases as the thickness of the stress relaxation material 9 increases. If the thickness of the stress relaxation material 9 exceeds 80 μm, the stress from the outside becomes infinitely small. Therefore, it is desirable that the thickness (dimension in the z direction) of the stress relaxation material 9 is, for example, 35 to 80 μm, more specifically 45 to 80 μm.

The second gauge resistor 320B is arranged on the substrate 30 in a region around the first gauge resistor 320A without overlapping with the hollow portion 360 when viewed in the z direction, and is provided to correct detection information of the first gauge resistor 320A.

At least a portion of the first gauge resistor 320A overlaps with the hollow portion 360 when viewed in the z direction, so that external detection information including an outside air pressure can be acquired. On the other hand, the second gauge resistor 320B does not overlap with the hollow portion 360 when viewed in the z direction, but overlaps with a portion of the substrate 30 in the region around the first gauge resistor 320A. Therefore, external detection information excluding the outside air pressure can be acquired from the first gauge resistor 320A. That is, the second gauge resistor 320B is arranged to differ only in the change in outside air pressure as compared to the change detected by the first gauge resistor 320A. For example, if the first gauge resistor 320A and the second gauge resistor 320B have the same structure, the only difference is whether or not they overlap with the hollow portion 360. There is no need to correct the difference in electric signal due to the difference in the structure of the two gauge resistors themselves. Therefore, this is desirable.

Further, the first gauge resistor 320A and the second gauge resistor 320B are spaced apart from each other in the y direction. Since the first gauge resistor 320A is spaced apart from the second gauge resistor 320B, it is possible to suppress the influence of the gauge resistances on each other and to derive the change in outside air pressure with high accuracy. Further, it is desirable to bring the detection environments of the first gauge resistor 320A and the second gauge resistor 320B closer to each other, except for whether they overlap with the hollow portion 360. For example, it is desirable that the first gauge resistor 320A and the second gauge resistor 320B are arranged close to each other within a range in which the gauge resistances do not affect each other.

The first gauge resistor 320A and the second gauge resistor 320B output respective detection information to the electronic component 2 as electrical signals. The electronic component 2 multiplexes the electrical signal detected by the temperature sensor, the electrical signal detected by the first gauge resistor 320A, and the electrical signal detected by the second gauge resistor 320B by a multiplexer, and converts the electrical signals to digital signals by an analog/digital conversion circuit. Then, based on the converted digital signals, the signal processing part performs processing such as amplification, filtering, and logic operation while using a memory area of a memory part. The signals subjected to the signal processing are outputted from the electronic component 2 to the outside of the MEMS module A1 via the wiring 4b and the substrate 1. At this time, the electronic component 2 corrects the detection information detected by the MEMS element 3 based on the difference between the detection information detected by the first gauge resistor 320A of the MEMS element 3 and the detection information detected by the second gauge resistor 320B for correction. Specifically, the detection information detected by the MEMS element 3 is corrected by subtracting a second voltage difference caused by a change in resistance value of the second gauge resistor 320B with respect to the voltage detected in the circuit including second gauge resistor 320B from a first voltage difference caused by a change in resistance value of the first gauge resistor 320A with respect to the voltage detected in the circuit including the first gauge resistor 320A. As a result, it is possible to obtain the MEMS module A1 that corrects the air pressure detection signals by performing appropriate signal processing with the electronic component 2 and transmits a signal representing the calculated amount of change in air pressure to the MEMS element 3, and it is possible to derive a change in outside air pressure with high accuracy.

The wiring 4a conductively joins the electrode pad 11 of the substrate 1 to the electrode pad 34 of the MEMS element 3, the wiring 4b conductively joins the electrode pad 11 of the substrate 1 to the electrode pad 21 of the electronic component 2, and the wiring 4c conductively joins the electrode pad 34 of the MEMS element 3 to the electrode pad 21 of the electronic component 2. The wirings 4a, 4b, and 4c are made of a metal such as Au or the like. The material of the wirings 4a, 4b, and 4c is not limited to Au, and may be Al, Cu, or the like. The wirings 4a, 4b, and 4c are appropriately joined to the electrode pads 11, 21, and 34.

The cover 6 is a box-shaped member made of a metal, and is joined to the holding surface 1a of the substrate 1 with a joining material 7 so as to surround the electronic component 2, the MEMS element 3, and the wirings 4a, 4b, and 4c. In the illustrated example, the cover 6 has a rectangular shape in a plan view. The cover 6 may be made of a material other than a metal. Further, the manufacturing method of the cover 6 is not particularly limited. The space between the cover 6 and the substrate 1 is hollow or filled with a soft resin such as a silicone resin or the like.

The cover 6 has an opening 61 and an extension portion 62, as shown in FIGS. 1 and 3. The opening 61 is used to introduce an outside air into the cover 6. Since the opening 61 is provided and the space between the cover 6 and the substrate 1 is hollow or filled with a soft resin, the first gauge resistor 320A and the second gauge resistor 320B for correction can detect the air pressure (e.g., the atmospheric pressure) around the MEMS module A1. Further, by providing the opening 61, the temperature sensor of the electronic component 2 can detect the air temperature around the MEMS module A1. In the present embodiment, one opening 61 is merely arranged at a position on the z1 direction side of the MEMS element 3. The number of openings 61 is not particularly limited. The extension portion 62 extends from the edge of the opening 61 and overlaps with at least a portion of the opening 61 in a plan view. The extension portion 62 is oriented in the z2 direction as it extends away from the edge of the opening 61, and is inclined as it comes close to the substrate 1. Further, in the illustrated configuration, the leading end of the extension portion 62 is provided at a position where it can avoid the electronic component 2 and the MEMS element 3 in a plan view. Further, the base of the extension portion 62 is provided at a position where it overlaps with the MEMS element 3. Further, the extension portion 62 may not be provided.

The joining material 7 is used to join the substrate 1 and the cover 6 to each other, and is made of, for example, a paste joining material containing a metal such as Ag or the like. In the present embodiment, the joining material 7 is provided in a rectangular annular shape in a plan view. A portion of the joining material 7 is formed in a region overlapping with the insulating layer 1C arranged on the holding surface 1a.

Next, a method for manufacturing the MEMS module A1 will be described.

First, a method for manufacturing the MEMS element 3 of the MEMS module A1 will be described.

As shown in FIG. 5, a substrate 30 having a semiconductor layer is prepared. Examples of the semiconductor layer include a silicon layer. The thickness of the substrate 30 is, for example, about 700 to 800 μm.

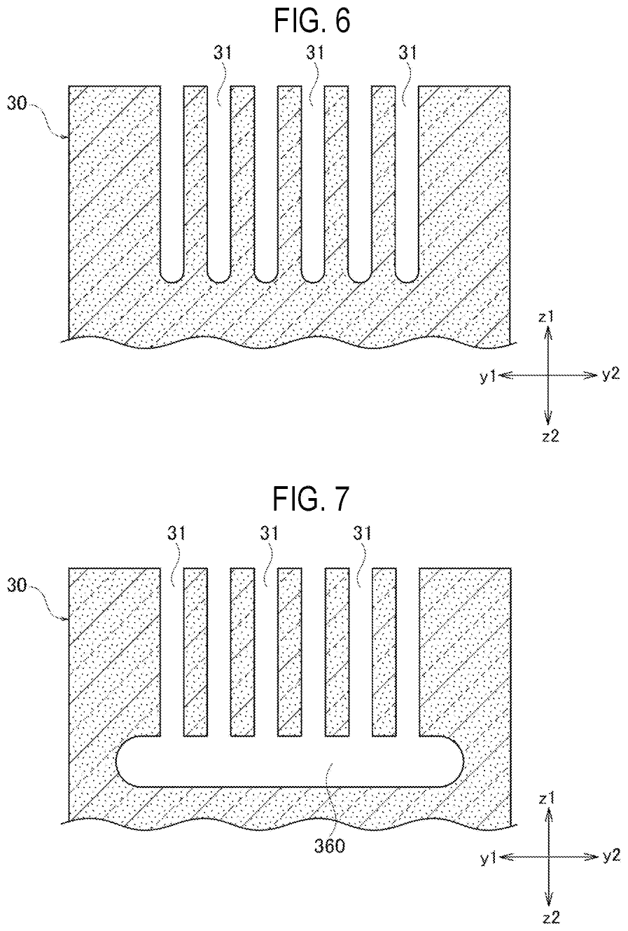

Next, as shown in FIG. 6, a plurality of groove portions 31 are formed in the substrate 30. The groove portions 31 can be formed by, for example, deep etching such as the Bosch method or the like. As an example of the dimensions of the plurality of groove portions 31, the diameter of the groove portions 31 having a circular shape in the z direction is 0.2 to 0.8 μm, and the pitch (center-to-center distance) of the adjacent groove portions 31 is 0.4 to 1.4 μm. Further, in the present embodiment, the dimensions of the plurality of groove portions 31 in the z direction are substantially the same.

Next, as shown in FIG. 7, the substrate 30 is etched from the bottom surfaces of the groove portions 31 in a direction perpendicular to the depth direction of the groove portions 31 to form a hollow portion 360 that connects the groove portions 31 (hollow portion forming step). In the hollow portion forming step, isotropic etching is performed so that the cross-sectional area perpendicular to the z direction gradually increases. Thus, the step of forming the groove portions 31 and the step of forming the hollow portion can be continuously performed by the same process, and the hollow portion 360 can be formed efficiently.

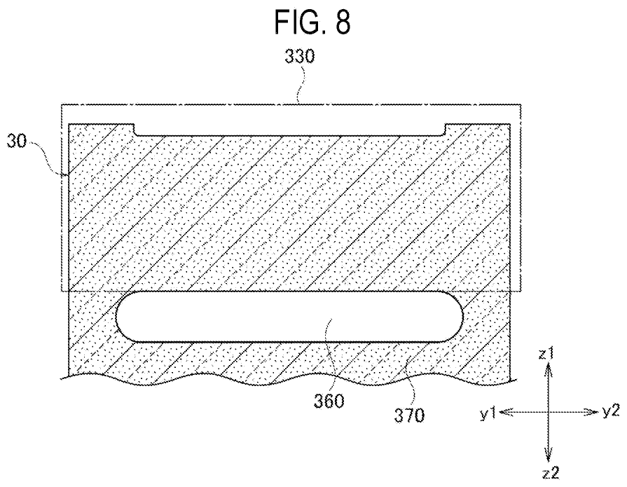

Next, as shown in FIG. 8, the substrate 30 is heat-treated (e.g., at 1100 to 1200 degrees C.) in an atmosphere containing hydrogen so that a portion of the substrate 30 melted by the heat treatment closes the groove portions 31. Thus, the hollow portion 360 is sealed. At the same time, the region 330 of the substrate 30 becomes a portion of the movable portion 340 (movable portion forming step). This manufacturing method does not require a step of joining a plurality of different members in order to form the movable portion 340 and the hollow portion 360. This provides an advantage that there is no concern of deterioration in sealing properties at a joining portion. In addition, there is an advantage that it is not necessary to provide an excessively large groove portion penetrating the substrate 30 in order to form the hollow portion 360.

In the movable portion forming step, the groove portions 31 are closed by partially moving the semiconductor layer using thermal migration. For this reason, the movable portion 340 is a portion, which is merely made of the material of the semiconductor layer, and is integrally connected to the fixed portion 370, which is also made of the material of the semiconductor layer, without a joining portion interposed therebetween. Thus, it is possible to improve the airtightness of the hollow portion 360.

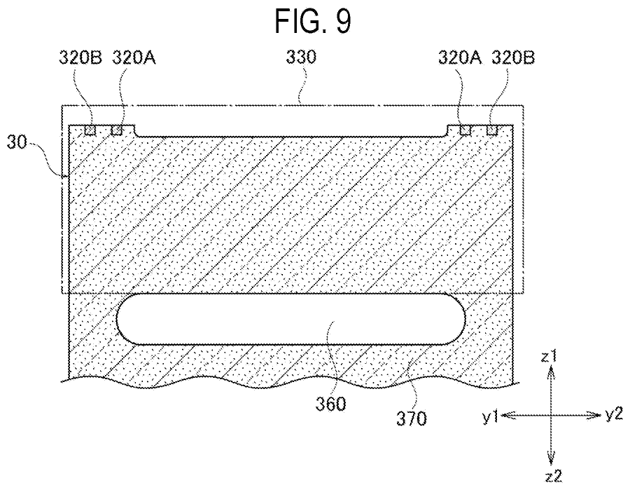

Next, as shown in FIG. 9, a first gauge resistor 320A is formed. Further, a second gauge resistor 320B is formed in the same process as the process for forming the first gauge resistor 320A. At least a portion of the first gauge resistor 320A overlaps with the hollow portion 360 when viewed in the z direction. The second gauge resistor 320B does not overlap with the hollow portion 360 when viewed in the z direction, but overlaps with a portion of the substrate 30 in the region around the first gauge resistor 320A.

As described above, the manufacturing cost of the MEMS module A1 can be reduced by forming the first gauge resistor 320A and the second gauge resistor 320B in the same process.

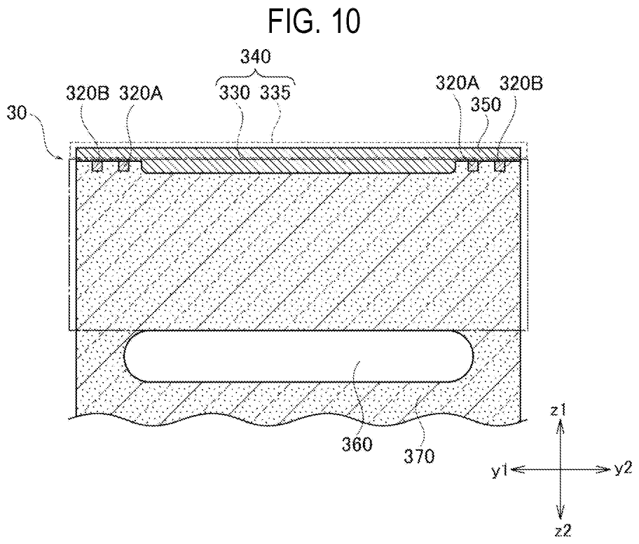

Further, the movable portion 340 includes a recess portion in the region 330. In order to increase the film thickness T of the movable portion 340, as shown in FIG. 10, an interlayer film 350 is formed on the main surface (recess portion) of the substrate 30 facing the z1 direction. The interlayer film 350 includes a region 335 functioning as a portion of the movable portion 340. Therefore, the movable portion 340 includes a region 330 of the substrate 30 and a region 335 of the interlayer film 350. As the interlayer film 350, for example, a silicon layer deposited by a CVD method may be used. Due to the interlayer film 350, the surface on which a protective film or the like is formed over the interlayer film 350 becomes a flat surface. This improves coatability of the protective film or the like.

The MEMS element 3 can be manufactured by the above steps.

In the present embodiment, a description is made by interpreting the first gauge resistor 320A and the second gauge resistor 320B as being included in the MEMS element 3. However, the present disclosure is not limited thereto. The first gauge resistor 320A and the second gauge resistor 320B may be interpreted as not being included in the MEMS element 3.

Next, as shown in FIG. 3, the electronic component 2 is held on the substrate 1, and the substrate 30 is held on the electronic component 2. The substrate 30 includes the MEMS element 3 including the first gauge resistor 320A and the second gauge resistor 320B. Furthermore, a wiring 4a and a wiring 4b for conductively joining the electrode pad 11 of the substrate 1 and the electrode pad 21 of the electronic component 2 or the electrode pad 34 of the MEMS element 3, and a wiring 4c for conductively joining the electrode pad 21 of the electronic component 2 and the electrode pad 34 of the MEMS element 3 are formed. Finally, the cover 6 and the substrate 1 are joined by a joining material 7.

Through the above steps, the MEMS module A1 can be manufactured. The MEMS module A1 includes the first gauge resistor 320A, and the second gauge resistor 320B arranged such that merely the change in outside air pressure differs as compared to the change detected by the first gauge resistor 320A. According to the MEMS module A1, the change in air pressure detected by the MEMS element 3 can be corrected based on the difference between the amount of change detected by the first gauge resistor 320A and the amount of change detected by the second gauge resistor 320B, which is inputted to the electronic component 2.

### <Example of Operation of MEMS Module A1>

An example of the operation of the MEMS module A1 will be described below. The present disclosure is not limited to the following operation example.

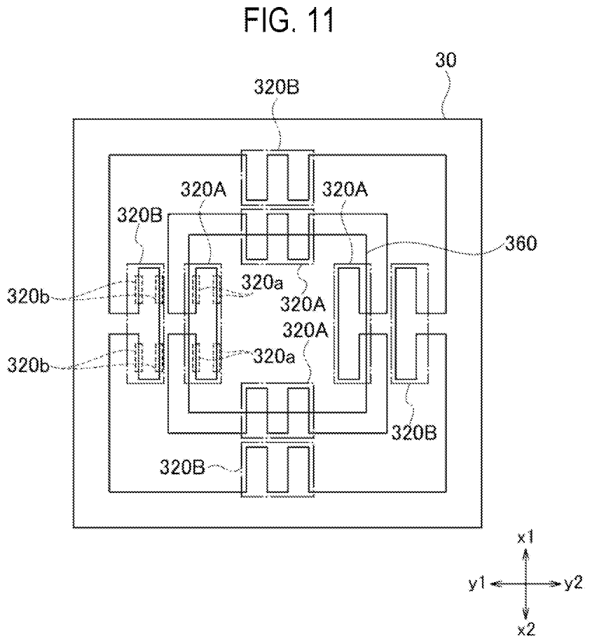

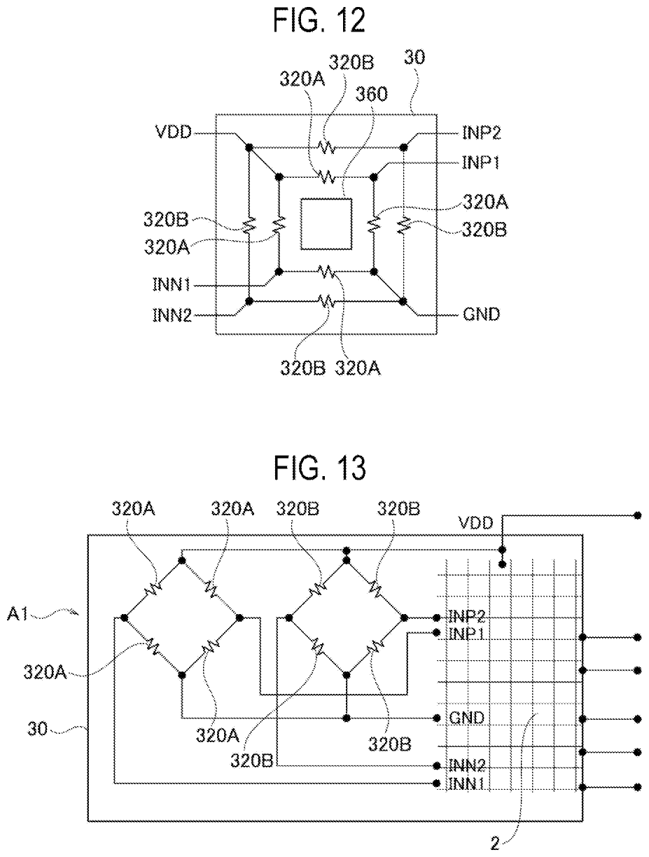

FIG. 11 is a layout diagram showing the MEMS module A1 described above. FIG. 12 is a schematic top view of the MEMS module A1 described above. FIG. 13 is an equivalent circuit diagram of the MEMS module A1 described above. In the following descriptions, the MEMS module A1 will be specifically described.

The MEMS element 3 of the MEMS module A1 includes, for example, four first gauge resistors 320A on the substrate 30. Each first gauge resistor 320A is configured by connecting four resistive elements 320a in series. The first gauge resistor 320A is electrically connected to the adjacent first gauge resistor 320A. The resistive elements 320a of each first gauge resistor 320A are arranged to extend in the same direction (e.g., in the x direction) as shown in FIG. 11. The resistive elements 320a are formed, for example, by implanting impurities into the substrate 30 by an ion implantation method using a photoresist film patterned by photolithography as a mask. In addition, there are four connection points where the first gauge resistors 320A are connected to each other. The first connection point is connected to a power supply terminal VDD, the second connection point is connected to a ground terminal GND, the third connection point is connected to an input terminal INP1 of the electronic component 2, and the fourth connection point is connected to an input terminal INN1 of the electronic component 2.

Similar to the first gauge resistors 320A, the MEMS element 3 of the MEMS module A1 includes, for example, four second gauge resistors 320B on the substrate 30. Each second gauge resistor 320B is configured by connecting four resistive elements 320b in series.

Each second gauge resistor 320B is electrically connected to the adjacent second gauge resistor 320B. The resistive elements 320b of each second gauge resistor 320B are arranged to extend in the same direction (e.g., in the x direction). In addition, there are four connection points where the second gauge resistors 320B are connected to each other. The first connection point is connected to the power supply terminal VDD, the second connection point is connected to the ground terminal GND, the third connection point is connected to an input terminal INP2 of the electronic component 2, and the fourth connection point is connected to an input terminal INN2 of the electronic component 2.

The electronic component 2 is connected to the power supply terminal VDD and the ground terminal GND. In the electronic component 2, the detection results of the first gauge resistor 320A and the second gauge resistor 320B for correction of the MEMS element 3 are inputted to the input terminals (INP1, INN1, INP2 and INN2). The voltage inputted to the input terminal INP1 is indicated as V_{INP1}, the voltage inputted to the input terminal INN1 is indicated as V_{INN1}, the voltage inputted to the input terminal INP2 is indicated as V_{INP2}, and the voltage inputted to the input terminal INN2 is indicated as V_{INN2}.

The electronic component 2 can correct the change in air pressure detected by the MEMS element 3 based on the difference [(V_{INP1}−V_{INN1})-(V_{INP2}−V_{INN2})] between the change detected by the first gauge resistor 320A of the MEMS element 3 (the difference between V_{INP1} and V_{INN1}) and the change detected by the second gauge resistor 320B of the MEMS element 3 (the difference between V_{INP2} and V_{INN2}). Therefore, the MEMS module A1 can accurately derive a change in outside air pressure.

According to the present embodiment, the MEMS module A1 including the first gauge resistor 320A and the second gauge resistor 320B arranged to differ merely in the change in outside air pressure as compared to the change detected by the first gauge resistor 320A can accurately derive a change in outside air pressure.

### OTHER EMBODIMENTS

Although one embodiment has been described above, the description and drawings forming a part of the present disclosure are exemplary and should not be construed as being limitative. Various alternative embodiments, implementations and operational techniques will become apparent to those skilled in the art from this disclosure. Thus, the present disclosure includes various embodiments and the like which are not described herein.

According to the present disclosure in some embodiments, it is possible to provide a MEMS module capable of accurately deriving a change in outside air pressure.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A MEMS module comprising:
a MEMS element provided with a substrate in which a hollow portion is formed, the MEMS element including:
a movable portion of the substrate which covers the hollow portion and has a thickness that allows a shape of the movable portion to be deformable by an air pressure difference between an air pressure inside the hollow portion and an air pressure outside the substrate;
a first gauge resistor arranged on the substrate such that at least a portion of the first gauge resistor overlaps with the hollow portion when viewed in a thickness direction of the movable portion; and
a second gauge resistor arranged on the substrate in a region surrounding the first gauge resistor without overlapping with the hollow portion when viewed in the thickness direction of the movable portion; and
an electronic component configured to correct detection information of the MEMS element by using a first electrical signal detected by the first gauge resistor and a second electrical signal detected by the second gauge resistor and calculate an amount of change in air pressure.

2. The MEMS module of claim 1, wherein the correction of the detection information is performed by subtracting a voltage difference generated by a change in resistance value of the second gauge resistor with respect to a voltage detected in a circuit including the second gauge resistor from a voltage difference generated by a change in resistance value of the first gauge resistor with respect to a voltage detected in a circuit including the first gauge resistor.

3. The MEMS module of claim 1, further comprising:
a wiring having a region located on an outer edge side of the substrate when viewed in a direction perpendicular to the thickness direction of the movable portion,
wherein the first electrical signal and the second electrical signal are transmitted from the MEMS element to the electronic component via the wiring.

4. The MEMS module of claim 1, wherein the electronic component is mounted on the substrate, and
wherein the MEMS element and the electronic component are spaced apart from each other.

5. The MEMS module of claim 1, further comprising:
a stress relaxation material arranged between the MEMS element and the electronic component.

6. The MEMS module of claim 1, wherein the first gauge resistor and the second gauge resistor have a structure identical to each other.

7. The MEMS module of claim 1, wherein the first gauge resistor and the second gauge resistor are spaced apart from each other when viewed in a direction perpendicular to the thickness direction of the movable portion.

8. The MEMS module of claim 1, wherein the substrate is made of silicon.
